(19) United States
(12) Patent Application Publication
(10) Pub. No.: US 2026/0247998 A1
(43) Pub. Date: Aug. 20, 2026

(54) VERTICAL INTERCONNECT BRIDGES FOR SEMICONDUCTOR DEVICE ASSEMBLIES

(71) Applicant: Micron Technology, Inc., Boise, ID (US)

(72) Inventors: Chesheng KUNG, Taichung City (TW); Chien Hao HSU, Taichung City (TW); Bang-Ning HSU, Tainan City (TW)

(21) Appl. No.: 19/460,447

(22) Filed: Jan. 27, 2026

Related U.S. Application Data
(60) Provisional application No. 63/760,242, filed on Feb. 19, 2025.

(51) Int. Cl. H10W 70/60; H10W 72/00; H10W 90/00; H10W 90/20; H10W 90/24

(52) U.S. Cl. CPC H10W 70/616; H10W 72/07234; H10W 90/24; H10W 90/275; H10W 90/291; H10W 90/724; H10W 90/732

(57) ABSTRACT

Implementations described herein relate to various semiconductor device assemblies. In some implementations, a semiconductor device assembly may include a plurality of semiconductor dies stacked on an interconnect structure in a first direction, where a first semiconductor die overhangs a second semiconductor die in a second direction, forming a first overhang portion of the first semiconductor die, and where the second direction is substantially perpendicular to the first direction. The semiconductor device assembly may further include a vertical interconnect bridge disposed on the interconnect structure, where the vertical interconnect bridge is electrically coupled to the first overhang portion of the first semiconductor die and provides an electrical connection between the first semiconductor die and the interconnect structure.

### CROSS-REFERENCE TO RELATED APPLICATION

This Patent Application claims priority to U.S. Provisional Patent Application No. 63/760,242, filed on Feb. 19, 2025, entitled “VERTICAL INTERCONNECT BRIDGES FOR SEMICONDUCTOR DEVICE ASSEMBLIES,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to through silicon via bridges for semiconductor device assemblies.

### BACKGROUND

A semiconductor package may include an interconnect structure (e.g., a semiconductor substrate, a redistribution layer (RDL), an interposer, or a similar interconnect structure, sometimes referred to herein collectively as “substrate” for ease of description), one or more semiconductor electronic components coupled to and/or embedded in the interconnect structure, and a casing formed over the interconnect structure to encapsulate the one or more semiconductor electronic components. The one or more semiconductor electronic components may be interconnected by electrical interconnects to form one or more semiconductor devices, such as one or more integrated circuits (ICs) (e.g., one or more dies or chips). For example, the semiconductor electronic components and the electrical interconnects may be fabricated on a semiconductor wafer to form one or more ICs before being diced into dies or chips and then packaged. A semiconductor package may be referred to as a semiconductor chip package that includes one or more ICs. A semiconductor package protects the semiconductor electronic components and the electrical interconnects from damage and includes a mechanism for connecting the semiconductor electronic components and the electrical interconnects to external components (e.g., a circuit substrate), such as via balls, pins, leads, contact pads, or other electrical interconnect structures. A semiconductor device assembly may be or may include a semiconductor package, multiple semiconductor packages, and/or one or more components of a semiconductor package (e.g., one or more semiconductor devices with or without a casing).

An electronic system assembly may include multiple semiconductor packages electrically coupled to a carrier substrate (e.g., circuit substrate). An electronic system assembly may include additional system components electrically coupled to the carrier substrate. The carrier substrate may include electrical interconnects and conductive paths used for interconnecting system components, including the multiple semiconductor packages and other system components of the electronic system assembly. Accordingly, the multiple semiconductor packages may be electrically connected to each other and/or to one or more additional system components via the carrier substrate to form the electronic system assembly. By way of example, other system components may include passive components (e.g., storage capacitors), processing units (e.g., a central processing unit (CPU), a graphics processing unit (GPU), a microprocessor, and/or a microcontroller), control units (e.g., a microcontroller, a memory controller, and/or a power management controller), or one or more other electronic components.

### BRIEF DESCRIPTION OF THE DRAWINGS

FIG. 1 is a diagram of an example apparatus that may be manufactured using techniques described herein.

FIG. 2 is a diagram of an example memory device that may be manufactured using techniques described herein.

FIGS. 3A-3B are diagrams of example apparatuses that include stacked semiconductor dies and one or more vertical interconnect bridges.

FIGS. 4A-4E are diagrams of an example process used to fabricate a semiconductor package including a vertical interconnect bridge.

FIGS. 4F-4G are diagrams of additional optional steps associated with the example process shown in FIGS. 4A-4E.

FIG. 5 is a diagram of example equipment used to manufacture various semiconductor packages, semiconductor dies, memory devices, or similar components described herein.

FIG. 6 is a flowchart of an example method of forming an integrated assembly or memory device having one or more vertical interconnect bridges.

### DETAILED DESCRIPTION

For certain semiconductor devices, there is a continual push for increased performance. For example, in the context of semiconductor memory, such as dynamic random-access memory (DRAM) modules or similar devices, there is a continual push to increase bandwidth of the devices. “Bandwidth” refers to the rate at which data can be read from or written to the memory device. Higher bandwidth means that more data can be transferred in a given amount of time, leading to better performance, especially in applications that require rapid data access and processing, such as gaming, video editing, and scientific computations. In some examples, a memory device bandwidth may be increased by enlarging a semiconductor die (e.g., DRAM die) size, thus increasing the area on the die that is available for input/output (I/O) connections (sometimes referred to herein as the “beachfront” area of the die) to accommodate more pads for signal transmission. However, increasing semiconductor die size may result in an unusable form factor or may lead to increased costs and design complications.

In some other examples, in order to increase bandwidth or otherwise increase performance, multiple semiconductor dies may be stacked, to form high-density memory packages or similar semiconductor packages. However, stacking dies may result in certain challenges with respect to electrically connecting the stacked dies to a interconnect structure (e.g., a substrate, an RDL, an interposer, or a similar material upon which semiconductor devices and circuits are built). In some examples, interconnect pillars (e.g., copper bumps) may be used to electrically connect stacked dies to the interconnect structure, but the heights of such pillars may be constrained by the available space within standard packaging dimensions. Moreover, longer pillars may need to be spaced further apart (in the horizontal direction) from one another to avoid interference between adjacent pillars, reducing the usable beachfront area on higher dies in a die stack. In this regard, pillars may pragmatically be limited to certain heights, such as 50 micrometers (µm), among other examples. In some other examples, wire connections (e.g., gold wire) may be used to connect stacked dies to the interconnect structure. However, such wire connections may exhibit unacceptable resistance levels, may be unreliable, over large distances, leading to device errors or failure, or may otherwise pose manufacturing difficulties.

In some other examples, through silicon vias (TSVs) may be formed in the stacked dies in order to provide electrical connections to the die stack. A TSV is a vertical electrical connection that passes through a silicon die (e.g., DRAM die), enabling the integration of multiple layers of semiconductor devices in a three-dimensional (3D) stacking configuration. TSVs may be used to create high-density, high-performance semiconductor packages by providing direct electrical pathways between different layers or dies, reducing the distance that signals need to travel and thereby improving signal speed and reducing power consumption. However, such TSVs result in a reduction of a functional silicon area of a die (e.g., the portion of the silicon die that contains the active circuitry responsible for the primary functions of the memory device), because large portions of the die may be used to accommodate the TSVs and thus may be free of integrated circuits, among other examples. In this way, stacking dies to form high-density memory modules may have many challenges and drawbacks.

Some implementations described herein are directed to a semiconductor device assembly or semiconductor package that enables increased DRAM bandwidth without the need for expanding die width or incurring significant design inefficiencies. More particularly, some implementations described herein enable high-density memory modules incorporating stacked dies and that avoid lengthy pillars (e.g., lengthy copper bumps), lengthy wire bonds, or TSVs in the functional silicon area of the stacked dies. In some implementations, the semiconductor device assembly may include a plurality of semiconductor dies stacked on an interconnect structure (e.g., a substrate, an RDL, an interposer, or a similar interconnect structure) in a vertical direction, including a base semiconductor die electrically coupled to the interconnect structure (e.g., via micro bumps or the like) and multiple stacked semiconductor dies that are stacked on the base semiconductor die. Each stacked semiconductor die may overhang, in the horizontal direction, another semiconductor die to form a respective overhang portion (e.g., beachfront area) of that semiconductor die for providing electrical connectivity to the interconnect structure. The semiconductor device assembly or semiconductor package may further include one or more vertical interconnect bridges (e.g., one or more TSV bridges, through glass via (TGV) bridges, through ceramic via (TCV) bridges, or similar vertical interconnect bridges, which are sometimes referred to herein collective as “TSV bridges” for ease of description) disposed on the interconnect structure and electrically connected thereto (e.g., via micro bumps or the like). A vertical interconnect bridge may be a silicon blank, a ceramic blank, a glass blank, or a similar blank (e.g., a silicon device, ceramic device, glass device, or similar device devoid of active circuitry associated with the primary functions of the memory device) that includes vertical interconnects (e.g., TSVs, TGVs, TCVs, or similar vertical interconnects) for electrically connecting upper dies to the interconnect structure or to other dies. In this way, each vertical interconnect bridge may be electrically coupled to at least one overhang portion of at least one stacked semiconductor die to provide an electrical connection between the at least one semiconductor die and the interconnect structure or another die. In some implementations, this configuration may be extended by stacking additional semiconductor dies or by using additional vertical interconnect bridges or varying heights of vertical interconnect bridges. Moreover, in some implementations, the semiconductor device assembly or semiconductor package may include die attach films (DAFs) to couple adjacent semiconductor dies to one another, or may employ pillar connections or wire connections to electrically connect stacked dies to the vertical interconnect bridges. The vertical interconnect bridges may vary in size based on their position in the stack to accommodate electrical connections to various overhang portions.

In this way, the semiconductor device assembly or semiconductor package described herein enables high-density memory packages without increasing the overall package height or significantly altering the compact form factor required by modern electronics. By leveraging the concept of vertical interconnect bridges, the devices and techniques described herein enable efficient use of the beachfront area on the dies for signal transmission (e.g., a total area of a data bus interface available for communication between the dies and external circuitry, such as a memory controller), thereby enhancing DRAM bandwidth without the conventional trade-offs of increased die size and inefficient design. As a result, quality or reliability of the semiconductor device may be improved, resulting in an amount of resources used to support a market consuming the semiconductor device (e.g., raw materials, semiconductor manufacturing tools, labor, and/or computing resources) being reduced. Moreover, the devices and techniques described herein provide a cost-effective means of increasing bandwidth potential by leveraging current substrate technology without the need for additional RDLs, and avoiding the complexity and expense associated with the incorporation of TSVs in the functional silicon area (e.g., within the DRAM dies, among other examples). Additionally, or alternatively, the semiconductor device assembly or semiconductor package may be compatible with existing industry processes, such as die-attach and molding, further conserving manufacturing resources associated with fabricating the semiconductor device assembly or enabling scalability to various package heights in accordance with application demands.

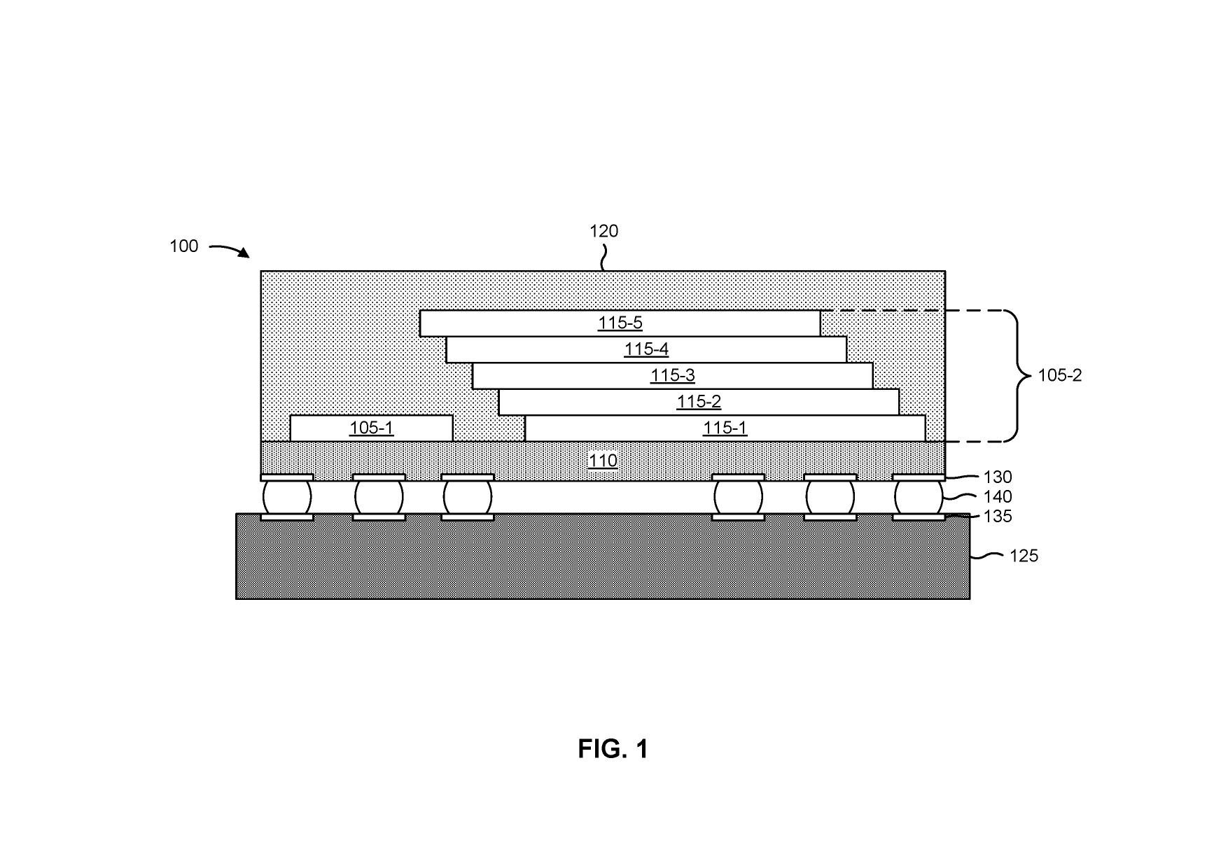

FIG. 1 is a diagram of an example apparatus 100 that may be manufactured using techniques described herein. The apparatus 100 may include any type of device or system that includes one or more integrated circuits 105. For example, the apparatus 100 may include a memory device, a flash memory device, a NAND memory device, a NOR memory device, a random access memory (RAM) device, a read-only memory (ROM) device, a dynamic RAM (DRAM) device, a static RAM (SRAM) device, a synchronous dynamic RAM (SDRAM) device, a ferroelectric RAM (FeRAM) device, a magnetic RAM (MRAM) device, a resistive RAM (RRAM) device, a holographic RAM (HRAM) device, a compute express link (CXL) compliant device, a solid state drive (SSD), a microchip, and/or a system on a chip (SoC), among other examples. In some cases, the apparatus 100 may be referred to as a semiconductor package, an assembly, a semiconductor device assembly, or an integrated assembly.

As shown in FIG. 1, the apparatus 100 may include one or more integrated circuits 105, shown as a first integrated circuit 105-1 and a second integrated circuit 105-2, disposed on a substrate 110 or a similar interconnect structure. An integrated circuit 105 may include any type of circuit, such as an analog circuit, a digital circuit, a radiofrequency (RF) circuit, a power supply, a power management circuit, an input-output (I/O) chip, an application-specific integrated circuit (ASIC), a field-programmable gate array (FPGA), and/or a memory device (e.g., a NAND memory device, a NOR memory device, a RAM device, or a ROM device). An integrated circuit 105 may be mounted on or otherwise disposed on a surface of the substrate 110. Although the apparatus 100 is shown as including two integrated circuits 105 as an example, the apparatus 100 may include a different number of integrated circuits 105.

In some implementations, an integrated circuit 105 may include a single semiconductor die 115 (sometimes called a die), as shown by the first integrated circuit 105-1. In some implementations, an integrated circuit 105 may include multiple semiconductor dies 115 (sometimes called dies), as shown by the second integrated circuit 105-2, which is shown as including five semiconductor dies 115-1 through 115-5.

As shown in FIG. 1, for an integrated circuit 105 that includes multiple semiconductor dies 115, the semiconductor dies 115 may be stacked on top of each other to reduce a footprint of the apparatus 100. In some implementations, a spacer may be present between semiconductor dies 115 that are adjacent to one another in the stack to enable electrical separation and heat dissipation. The stacked semiconductor dies 115 may include three-dimensional electrical interconnects, such as TSVs, to route electrical signals between semiconductor dies 115. Although the integrated circuit 105-2 is shown as including five semiconductor dies 115, an integrated circuit 105 may include a different number of semiconductor dies 115 (e.g., at least two semiconductor dies 115). A first semiconductor die 115-1 (sometimes called a bottom die or a base die) may be disposed on the substrate 110, a second semiconductor die 115-2 may be disposed on the first semiconductor die 115-1, and so on. Although FIG. 1 shows the semiconductor dies 115 stacked in a shingle stack (e.g., with die edges that are not aligned, which provides space for wire bonding near the edges of the semiconductor dies 115), in some implementations, the semiconductor dies 115 may be stacked in a different arrangement, such as a straight stack (e.g., with aligned die edges).

The apparatus 100 may include a casing 120 that protects internal components of the apparatus 100 (e.g., the integrated circuits 105) from damage and environmental elements (e.g., particles) that can lead to malfunction of the apparatus 100. The casing 120 may be a mold compound, a plastic (e.g., an epoxy plastic), a ceramic, or another type of material depending on the functional requirements for the apparatus 100.

In some implementations, the apparatus 100 may be included as part of a higher level system (e.g., a computer, a mobile phone, a network device, an SSD, a vehicle, or an Internet of Things device), such as by electrically connecting the apparatus 100 to a circuit board 125, such as a printed circuit board. For example, the substrate 110 may be disposed on the circuit board 125 such that electrical contacts 130 (e.g., bond pads) of the substrate 110 are electrically connected to electrical contacts 135 (e.g., bond pads) of the circuit board 125.

In some implementations, the substrate 110 may be mounted on the circuit board 125 using solder balls 140 (e.g., arranged in a ball grid array), which may be melted to form a physical and electrical connection between the substrate 110 and the circuit board 125. Additionally, or alternatively, the substrate 110 may be mounted on and/or electrically connected to the circuit board 125 using another type of connector, such as pins or leads. Similarly, an integrated circuit 105 may include electrical pads (e.g., bond pads) that are electrically connected to corresponding electrical pads (e.g., bond pads) of the substrate 110 using electrical bonding, such as wire bonding, bump bonding, or the like. The interconnections between an integrated circuit 105, the substrate 110, and the circuit board 125 enable the integrated circuit 105 to receive and transmit signals to other components of the apparatus 100 and/or the higher level system.

As indicated above, FIG. 1 is provided as an example. Other examples may differ from what is described with regard to FIG. 1.

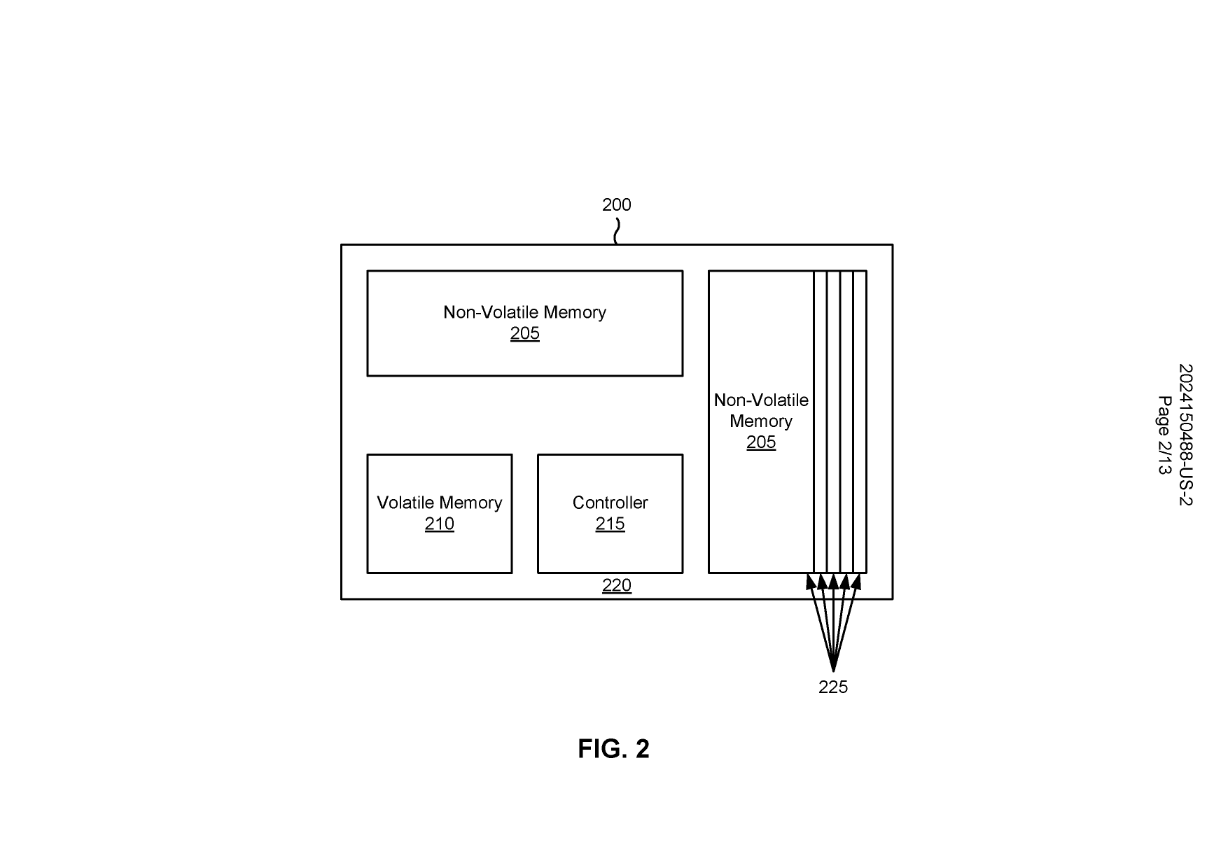

FIG. 2 is a diagram of an example memory device 200 that may be manufactured using techniques described herein. The memory device 200 is an example of the apparatus 100 described above in connection with FIG. 1. The memory device 200 may be any electronic device configured to store data in memory. In some implementations, the memory device 200 may be an electronic device configured to store data persistently in non-volatile memory 205. For example, the memory device 200 may be a hard drive, an SSD, a flash memory device (e.g., a NAND flash memory device or a NOR flash memory device), a universal serial bus (USB) thumb drive, a memory card (e.g., a secure digital (SD) card), a secondary storage device, a non-volatile memory express (NVMe) device, and/or an embedded multimedia card (eMMC) device.

As shown, the memory device 200 may include non-volatile memory 205, volatile memory 210, and a controller 215. The components of the memory device 200 may be mounted on or otherwise disposed on a substrate 220 or a similar interconnect structure. In some implementations, the non-volatile memory 205 includes a single die. Additionally, or alternatively, the non-volatile memory 205 may include multiple dies, such as stacked semiconductor dies 225 (e.g., in a straight stack, a shingle stack, or another type of stack), as described above in connection with FIG. 1.

The non-volatile memory 205 may be configured to maintain stored data after the memory device 200 is powered off. For example, the non-volatile memory 205 may include NAND memory or NOR memory. The volatile memory 210 may require power to maintain stored data and may lose stored data after the memory device 200 is powered off. For example, the volatile memory 210 may include one or more latches and/or RAM, such as DRAM and/or SRAM. As an example, the volatile memory 210 may cache data read from or to be written to non-volatile memory 205, and/or may cache instructions to be executed by the controller 215.

The controller 215 may be any device configured to communicate with the non-volatile memory 205, the volatile memory 210, and a host device (e.g., via a host interface of the memory device 200). For example, the controller 215 may include a memory controller, a system controller, an ASIC, an FPGA, a processor, a microcontroller, and/or one or more processing components. In some implementations, the memory device 200 may be included in a system that includes the host device. The host device may include one or more processors configured to execute instructions and store data in the non-volatile memory 205.

The controller 215 may be configured to control operations of the memory device 200, such as by executing one or more instructions (sometimes called commands). For example, the memory device 200 may store one or more instructions as firmware, and the controller 215 may execute those one or more instructions. Additionally, or alternatively, the controller 215 may receive one or more instructions from a host device via a host interface, and may execute those one or more instructions. For example, the controller 215 may transmit signals to and/or receive signals from the non-volatile memory 205 and/or the volatile memory 210 based on the one or more instructions, such as to transfer data to (e.g., write or program), to transfer data from (e.g., read), and/or to erase all or a portion of the non-volatile memory 205 (e.g., one or more memory cells, pages, sub-blocks, blocks, or planes of the non-volatile memory 205).

As indicated above, FIG. 2 is provided as an example. Other examples may differ from what is described with regard to FIG. 2. The number and arrangement of components shown in FIG. 2 are provided as an example. In practice, there may be additional components, fewer components, different components, or differently arranged components than those shown in FIG. 2.

In some examples, the apparatus 100 of FIG. 1 or the memory device 200 of FIG. 2 may be associated with certain bandwidth or size restraints. For example, in some applications it may be beneficial to increase a size of a semiconductor die (e.g., semiconductor die 115, non-volatile memory 205, or volatile memory 210) to increase bandwidth, such as by increasing a size of one or more DRAM dies in a memory device (e.g., memory device 200) in order to increase bandwidth. However, increasing semiconductor die size may result in an inefficient use of space or may lead to increased costs and design complications. In some other aspects, it may be beneficial to stack multiple semiconductor dies to increase bandwidth or for a similar purpose. However, a physical structure of such stacks, particularly the heights of interconnect pillars used for such stacks, may be constrained by the available space within standard packaging dimensions, or such stacks may require the use of TSVs in the functional silicon area of the semiconductor dies, resulting in reduced capacity or performance of each die.

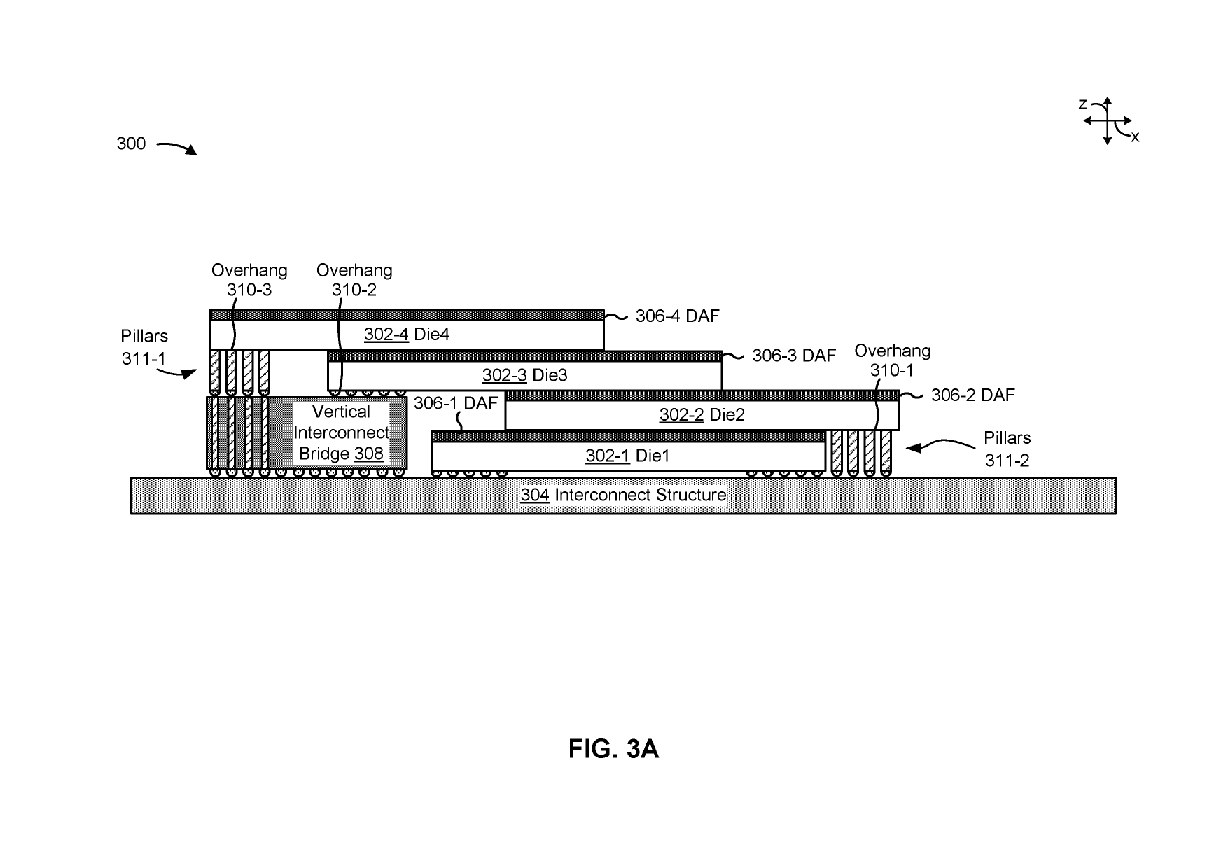

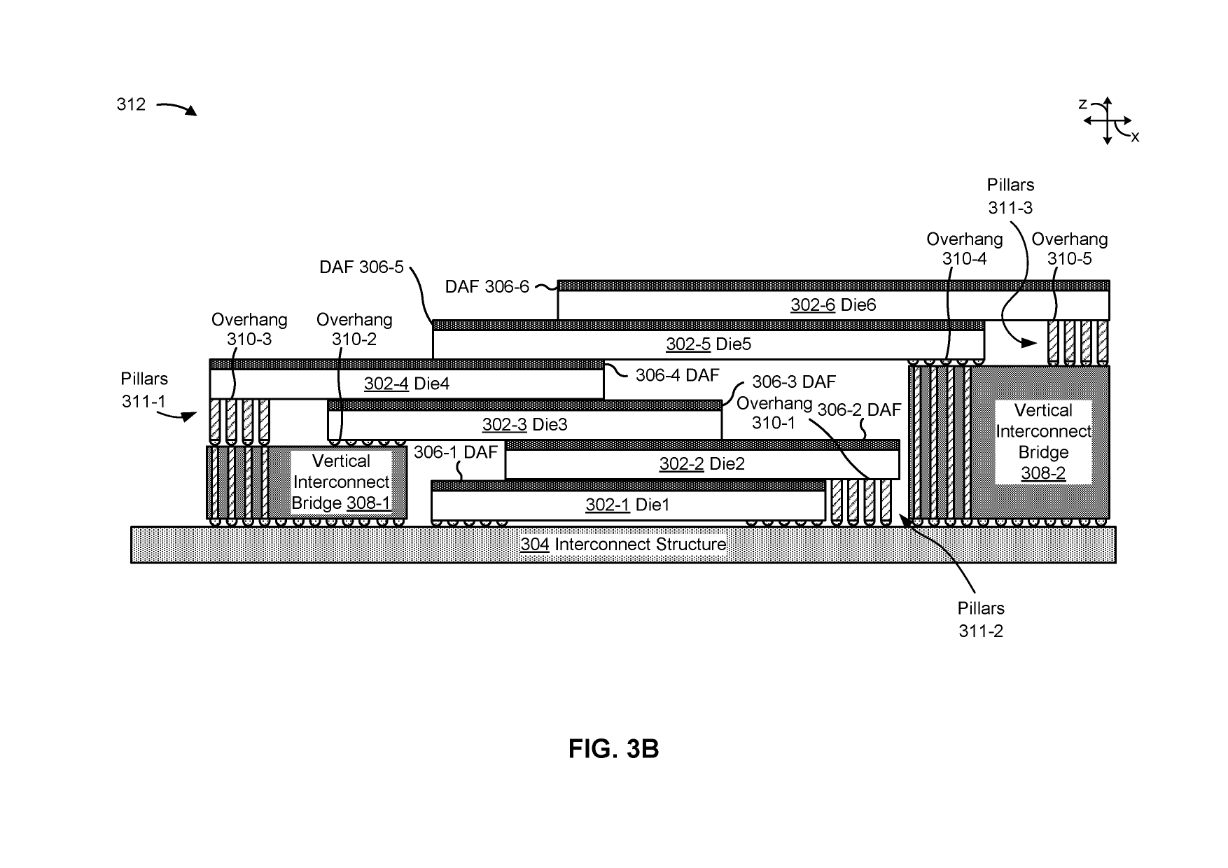

Some implementations and techniques described herein enable improved semiconductor device assemblies that exhibit increased bandwidth or smaller form factors than traditional semiconductor devices, without the need to use TSVs in a functional silicon area of the semiconductor dies. Aspects of the improved semiconductor device assemblies and methods of manufacturing such assemblies are described in more detail below in connection with FIGS. 3A-6.

FIGS. 3A-3B are diagrams of example apparatuses that include stacked semiconductor dies and one or more vertical interconnect bridges. The apparatuses shown and described in connection with FIGS. 3A-3B (e.g., apparatus 300 described in connection with FIG. 3A and apparatus 312 described in connection with FIG. 3B) may correspond to the apparatus 100 or the memory device 200. Additionally, or alternatively, each of the apparatuses shown and described in connection with FIGS. 3A-3B may be any type of device or system that includes one or more integrated circuits, such as a memory device, a flash memory device, a NAND memory device, a NOR memory device, a RAM device, a ROM device, a DRAM device, an SRAM device, an SDRAM device, an FeRAM device, an MRAM device, an RRAM device, an HRAM device, a CXL compliant device, an SSD, a microchip, and/or an SoC, among other examples. In some cases, the apparatus 300 or the apparatus 312 may be referred to as a semiconductor package, an assembly, a semiconductor device assembly, or an integrated assembly, among other examples.

As shown in FIG. 3A, apparatus 300 may include multiple semiconductor dies 302 (shown in FIG. 3A as a first semiconductor die 302-1 through a fourth semiconductor die 302-4, but which may include fewer or more semiconductor dies 302 in some other implementations) stacked on an interconnect structure 304 (e.g., a substrate, an RDL, an interposer, or a similar interconnect structure). More particularly, the apparatus may include the first semiconductor die 302-1 directly coupled to the interconnect structure 304, a second semiconductor die 302-2 stacked (in the vertical or z-axis direction) on top of the first semiconductor die 302-1, a third semiconductor die 302-3 stacked (in the vertical or z-axis direction) on top of the second semiconductor die 302-2, and the fourth semiconductor die 302-4 stacked (in the vertical or z-axis direction) on top of the third semiconductor die 302-3. In this regard, the first semiconductor die 302-2 may sometimes be referred to herein as a base semiconductor die or a bottom semiconductor die, and the remaining semiconductor dies (e.g., the second semiconductor die 302-2 through the fourth semiconductor die 302-4 in the example shown in FIG. 3A) may be referred to herein as stacked semiconductor dies. Additionally, or alternatively, the group of semiconductor dies 302 as a whole (e.g., the first semiconductor die 302-1 through the fourth semiconductor die 302-4 in the example shown in FIG. 3A) may be referred to herein as a stack of semiconductor dies, a semiconductor die stack, a die stack, or a stack, among other examples.

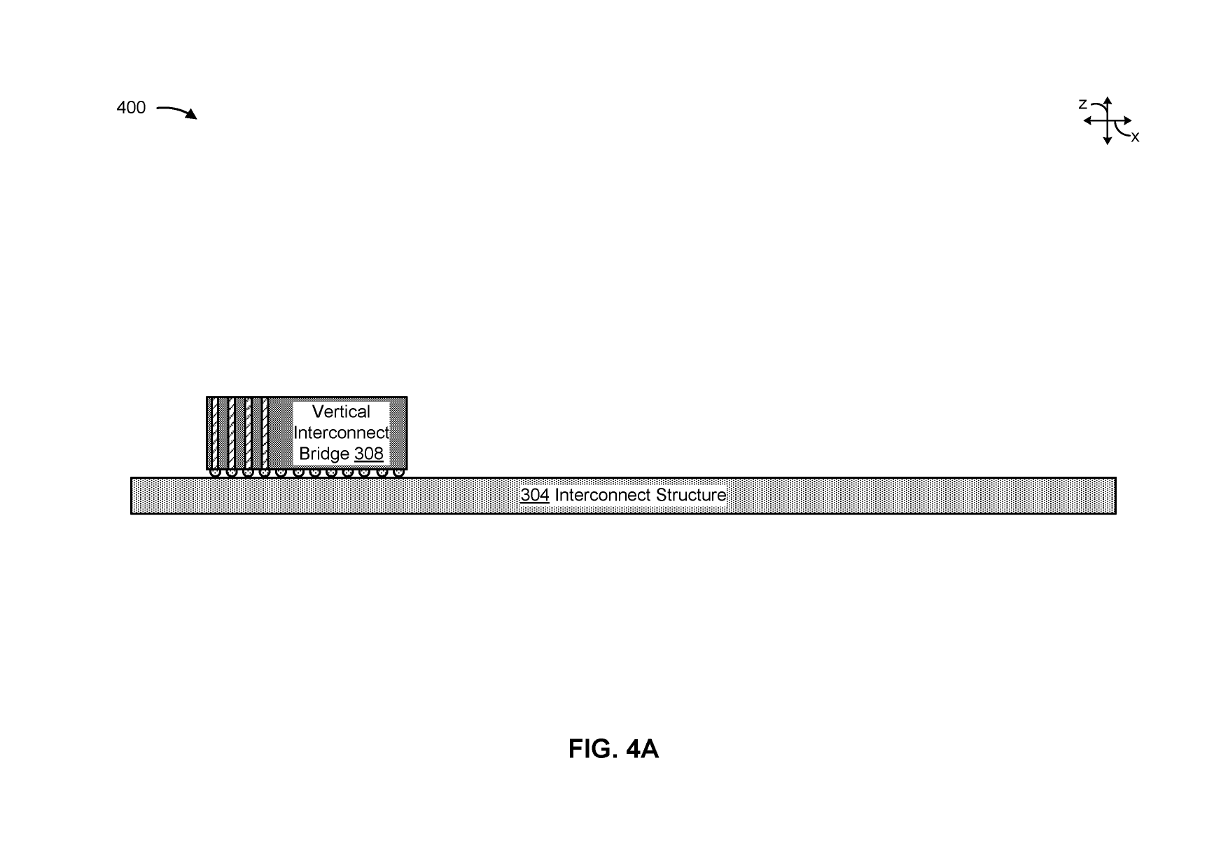

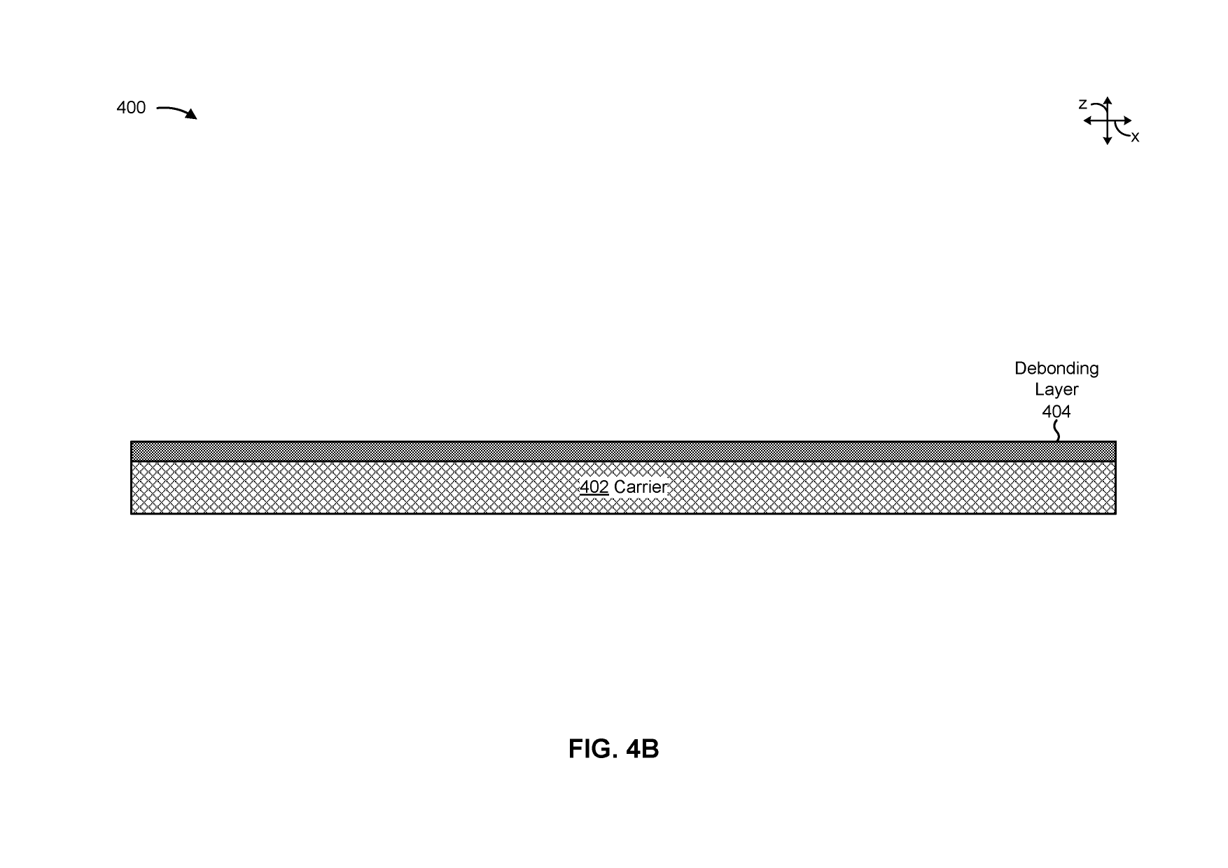

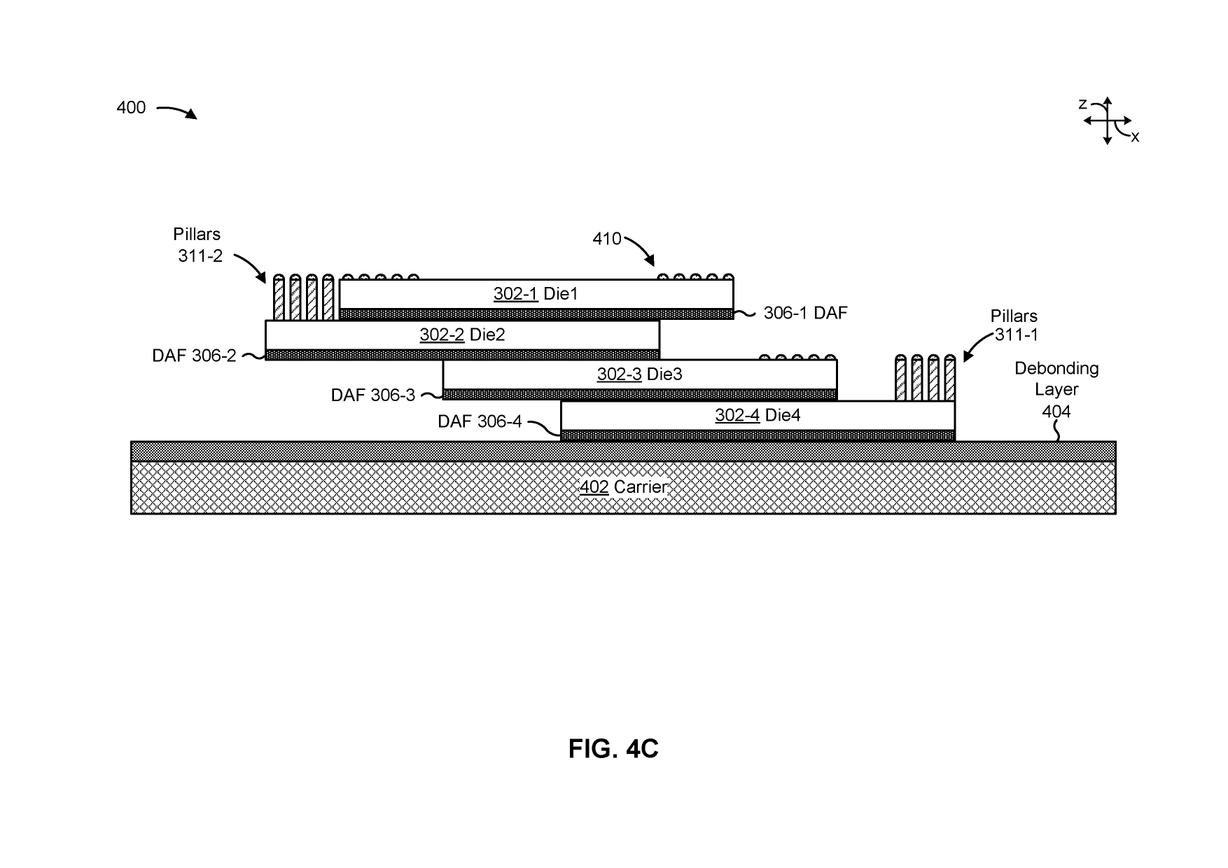

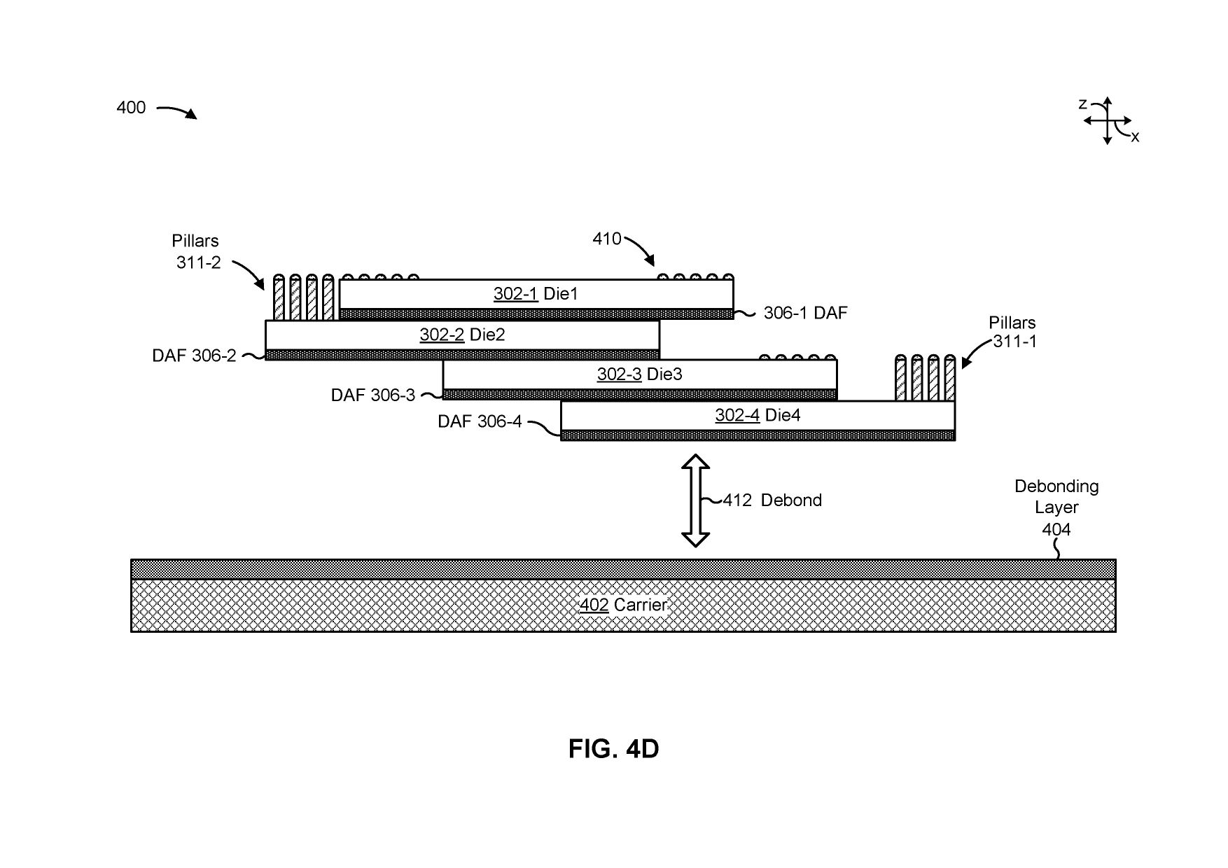

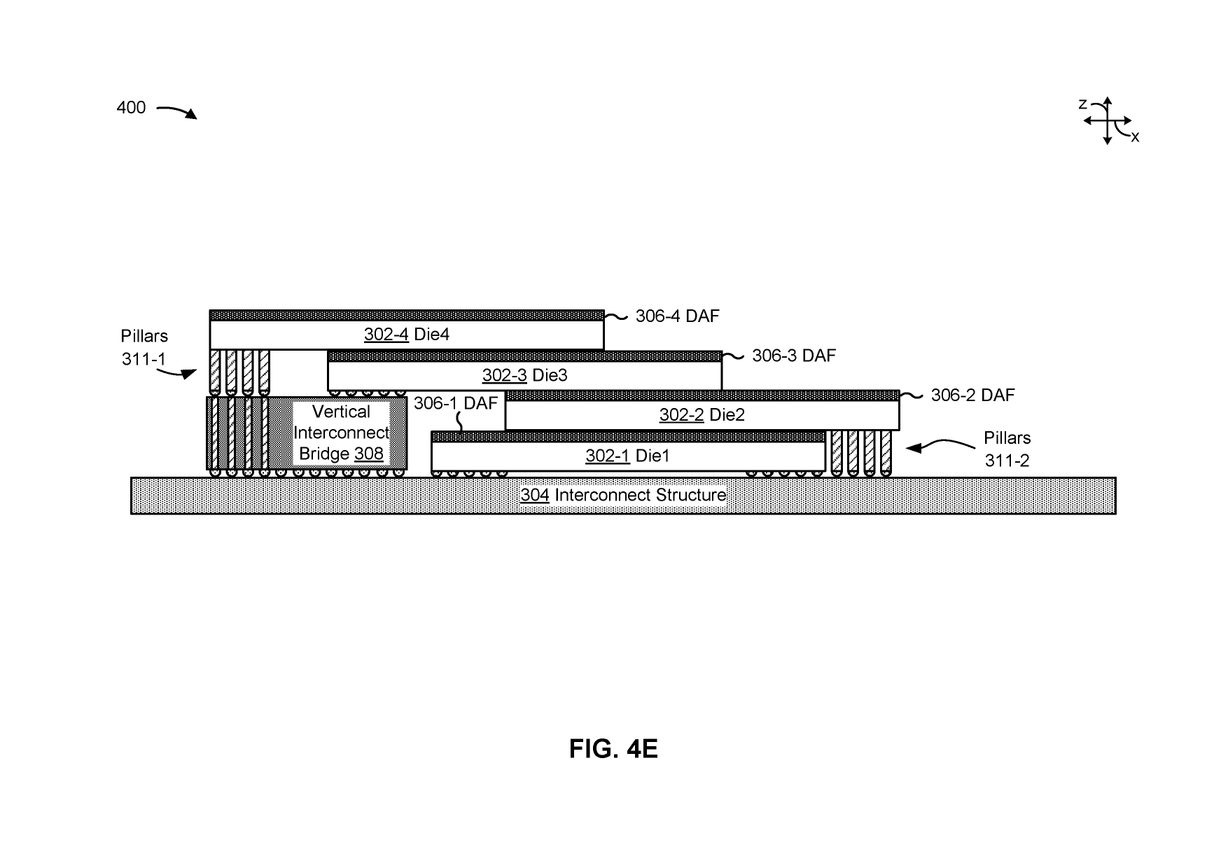

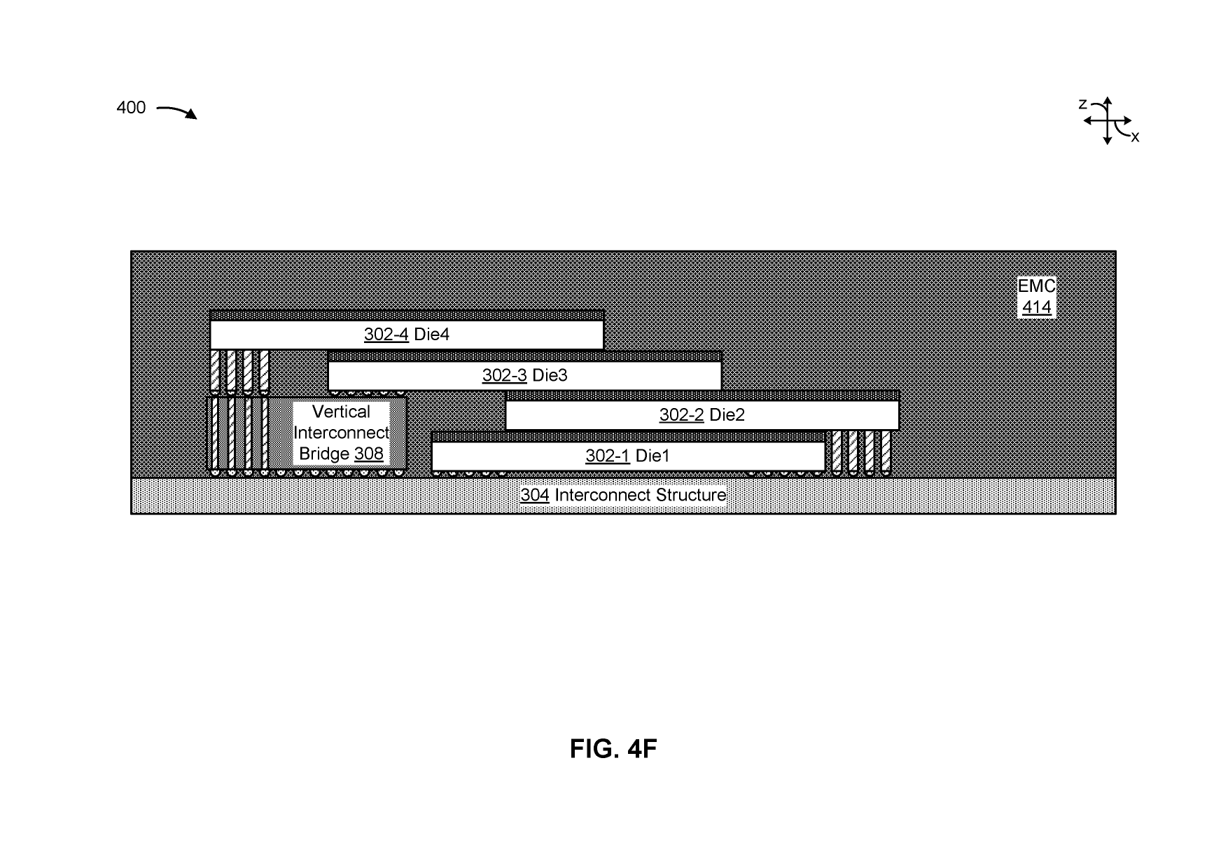

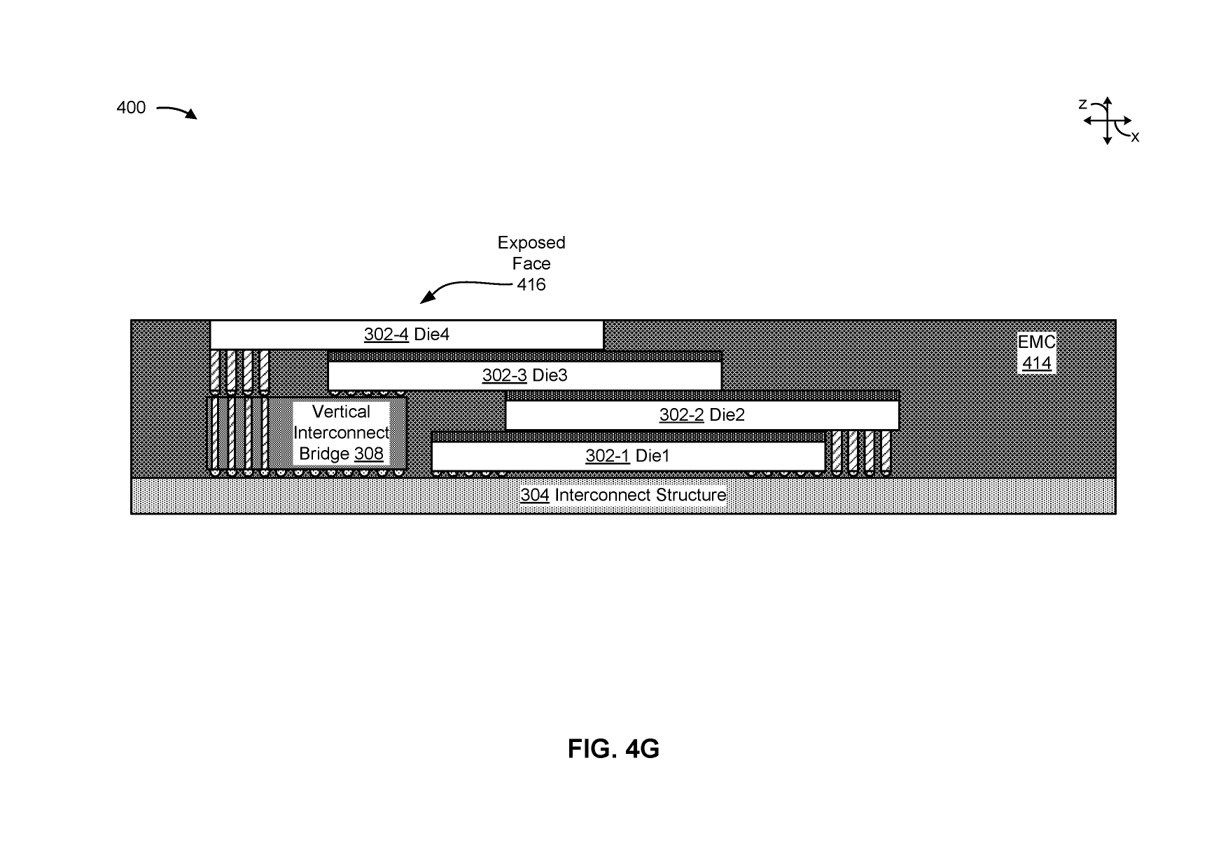

As further shown in FIG. 3A, in some implementations, the apparatus 300 may include a DAF 306 (e.g., a non-conductive film (NCF), among other examples) disposed between adjacent semiconductor dies 302 to couple the adjacent semiconductor dies 302 to one another. For example, the first semiconductor die 302-1 may be directly coupled to the interconnect structure 304, such as via micro bumps, solder balls, pins or leads, electrical pads (e.g., bond pads), electrical bonding (e.g., wire bonding, bump bonding, or the like), or similar interconnects that enable reception and transmission of transmit signals between the first semiconductor die 302-1 and the interconnect structure 304. Moreover, the first semiconductor die 302-1 may include a first DAF 306-1 that is used to couple the first semiconductor die 302-1 to the second semiconductor die 302-2. Similarly, the second semiconductor die 302-2 may include a second DAF 306-1 that is used to couple the second semiconductor die 302-2 to the third semiconductor die 302-3, or the third semiconductor die 302-3 may include a third DAF 306-3 that is used to couple the third semiconductor die 302-3 to the fourth semiconductor die 302-4. Moreover, the fourth semiconductor die 302-may include a fourth DAF 306-4 that may be used to attach additional semiconductor dies 302 in implementations in which more than four semiconductor dies 302 form a semiconductor die stack (e.g., as described in more detail below in connection with FIG. 3B). In some other implementations, such as implementations in which the fourth semiconductor die 302-4 forms the uppermost semiconductor die 302 of the semiconductor die stack, the fourth DAF 306-4 may optionally be removed during a manufacturing process (e.g., via grinding, among other examples), which is described in more detail below in connection with FIGS. 4A-4G.

In some implementations, the apparatus 300 may further include one or more vertical interconnect bridges 308 (e.g., TSV bridges, TGV bridges, TCV bridges, or similar vertical interconnect bridges) on the interconnect structure 304 (e.g., coupled to the interconnect structure 304 via micro bumps, solder balls, pins or leads, electrical pads (e.g., bond pads), electrical bonding (e.g., wire bonding, bump bonding, or the like), or a similar interconnect that enables reception and transmission of transmit signals between the vertical interconnect bridge 308 and the interconnect structure 304). The vertical interconnect bridge 308 may be a silicon component (e.g., a silicon blank), a ceramic component, a glass component, or a similar component including one or more vertical interconnects (e.g., one or more TSVs, TGVs, TCVs, or similar vertical interconnects) that enable electrical connections between components located above the vertical interconnect bridge 308 and below the vertical interconnect bridge 308. More particularly, the vertical interconnect bridge 308 may include vertical electrical connections (e.g., TSVs, TCVs, TGVs, or similar vertical electrical connections) that pass through the silicon, ceramic, glass, or similar material, enabling electrical connection between different layers of semiconductor dies 302 or between a semiconductor die 302 and the interconnect structure 304 or other interconnect structures. In that regard, the vertical interconnect bridge 308 may be used to facilitate electrical communication in stacked semiconductor assemblies without increasing the overall package height or requiring additional RDLs, among other examples. In some aspects, the vertical interconnect bridge 308 may be placed on the interconnect structure 304 and may be electrically coupled to overhang portions 310 (e.g., beachfront areas) of one or more semiconductor dies 302, providing an efficient means of interconnecting the semiconductor dies 302 vertically while maintaining a compact form factor of the overall apparatus 300.

More particularly, as further shown in FIG. 3A, the stack of semiconductor dies 302 may be stacked using a shingle stack configuration or similar configuration, such that certain die edges may be not aligned. In such implementations, one or more of the stacked semiconductor dies 302 (e.g., the second semiconductor die 302-2 through the fourth semiconductor die 302-4 in FIG. 3A) may overhang, in the horizontal direction, at least one other semiconductor die 302, forming a respective overhang portion 310 (e.g., beachfront area) of that semiconductor die 302. For example, the second semiconductor die 302-2 may overhang the first semiconductor die 302-1, forming a first overhang portion 310-1; the third semiconductor die 302-3 may overhang the second semiconductor die 302-2, forming a second overhang portion 310-2; or the fourth semiconductor die 302-4 may overhang the third semiconductor die 302-3, forming a third overhang portion 310-3.

In some implementations, the overhang portions 310 may be used to provide electrical connections (e.g., via use of pillar interconnects, wire interconnects, copper bumps, micro bumps, solder balls, pins or leads, electrical pads (e.g., bond pads), electrical bonding (e.g., wire bonding, bump bonding, or the like), or similar interconnects) between the stacked semiconductor dies 302 and the interconnect structure 304 without requiring the use of TSVs in a functional silicon area (e.g., without requiring TSVs in the semiconductor dies 302), among other examples. For example, in some implementations, an overhang portion 310 may be coupled to another semiconductor component (e.g., one of the interconnect structure 304 or a vertical interconnect bridge 308, as described in more detail below) via one or more pillar interconnects 311 (e.g., copper bumps), which may be copper posts or similar electrically conductive structures. In such implementations, a height of a pillar (e.g., a dimension in the vertical direction or z-axis direction) may be limited to a certain maximum height, such as for performance or manufacturability reasons, among other examples. For example, a pillar may be used to extend between two components across a distance in the z-axis direction that is approximately equal to a height of one semiconductor die 302 (including a corresponding DAF 306), but may not be used to extend between two components across a z-axis distance that spans multiple stacked semiconductor dies 302. In that regard, returning to the example shown in FIG. 3A, a first set of pillar interconnects 311-1 may be used to electrically couple the overhang portion 310-1 of the second semiconductor die 302-2 to the interconnect structure 304. However, pillar interconnects 311 may not be suitable to electrically couple the third semiconductor die 302-3 or fourth semiconductor die 302-4 to the interconnect structure 304, because a distance (in the vertical or z-axis dimension) between the respective overhang portions 310 and the interconnect structure 304 spans multiple z-axis dimensions of a semiconductor die 302.

In such implementations, the vertical interconnect bridge 308 may be used to electrically couple the third semiconductor die 302-3 or the fourth semiconductor die 302-4 to the interconnect structure 304 (e.g., the vertical interconnect bridge 308 may provide an electrical connection between one or more semiconductor dies and the interconnect structure 304). For example, the vertical interconnect bridge 308 may electrically couple the second overhang portion 310-2 of the third semiconductor die 302-3 to the interconnect structure 304, or the third overhang portion 310-3 of the fourth semiconductor die 302-3 to the interconnect structure 304. More particularly, as shown in FIG. 3A, the vertical interconnect bridge 308 may be directly coupled (e.g., directly bonded, soldered, or otherwise electrically coupled without the use of wire bonds or pillars, such as via micro bumps or similar electrical connections) to the third semiconductor die 302-3, and the vertical interconnect bridge 308 may be electrically coupled to the fourth semiconductor die 302-4 via a second set of pillar interconnects 311-2 (e.g., copper bumps), among other examples.

Although the example shown in FIG. 3A is associated with four semiconductor dies 302 (sometimes referred to as a “4H” semiconductor package) and one vertical interconnect bridge 308, in some other implementations, a semiconductor device assembly may include fewer or more semiconductor dies 302 or multiple vertical interconnect bridges 308. For example, in some implementations, the design or aspects described above in connection with FIG. 3A may be scaled up to accommodate a semiconductor package associated with six semiconductor dies 302 (e.g., a 6H semiconductor package), eight semiconductor dies 302 (e.g., an 8H semiconductor package), twelve semiconductor dies 302 (e.g., a 12H semiconductor package), sixteen semiconductor dies 302 (e.g., a 16H semiconductor package), or similar semiconductor packages.

For example, FIG. 3B shows an example apparatus 312 associated with a 6H semiconductor package. As shown in FIG. 3B, the apparatus 312 may be associated with a fifth semiconductor die 302-5 and a sixth semiconductor die 302-6, in addition to the four semiconductor dies 302 described above in connection with FIG. 3A. Moreover, as shown in FIG. 3B, the fifth semiconductor die 302-5 may overhang the fourth semiconductor die 302-4, forming a fourth overhang portion 310-4; or the sixth semiconductor die 302-6 may overhang the fifth semiconductor die 302-5, forming a fifth overhang portion 310-5.

In this implementation, the apparatus 312 may include multiple vertical interconnect bridges 308 (e.g., multiple TSV bridges), including a first vertical interconnect bridge 308-1 and a second vertical interconnect bridge 308-2. The first vertical interconnect bridge 308-1 may be substantially similar to the vertical interconnect bridge 308 described above in connection with FIG. 3A, and thus may be used to electrically couple the third semiconductor die 302-3 or the fourth semiconductor die 302-4 to the interconnect structure 304 in a similar manner as described above. For example, the first vertical interconnect bridge 308-1 may electrically couple the second overhang portion 310-2 of the third semiconductor die 302-3 to the interconnect structure 304, or the third overhang portion 310-3 of the fourth semiconductor die 302-3 to the interconnect structure 304. More particularly, the first vertical interconnect bridge 308-1 may be directly coupled (e.g., directly bonded, soldered, or otherwise electrically coupled without the use of wire bonds or pillars) to the third semiconductor die 302-3, and the first vertical interconnect bridge 308-1 may be electrically coupled to the fourth semiconductor die 302-4 via a second set of pillar interconnects 311-2 (e.g., copper bumps), among other examples.

Similarly, the second vertical interconnect bridge 308-2 may be used to electrically couple the fifth semiconductor die 302-5 or the sixth semiconductor die 302-6 to the interconnect structure 304. For example, the second vertical interconnect bridge 308-2 may electrically couple the fourth overhang portion 310-4 of the fifth semiconductor die 302-5 to the interconnect structure 304 or the fifth overhang portion 310-5 of the sixth semiconductor die 302-6 to the interconnect structure 304. More particularly, the second vertical interconnect bridge 308-2 may be directly coupled (e.g., directly bonded, soldered, or otherwise electrically coupled without the use of wire bonds or pillars) to the fifth semiconductor die 302-5, and the second vertical interconnect bridge 308-2 may be electrically coupled to the sixth semiconductor die 302-6 via a third set of pillar interconnects 311-3 (e.g., copper bumps), among other examples. In such implementations, the multiple vertical interconnect bridges 308 may have different heights (e.g., dimensions in the vertical or z-axis direction), such as for a purpose of accommodating the different relative elevations of the various semiconductor dies 302. Put another way, in the example shown in FIG. 3B, a height of the first vertical interconnect bridge 308-1 may be smaller than a height of the second vertical interconnect bridge 308-2.

In some implementations, the apparatus 300 or the apparatus 312 may further include a casing (not shown in FIGS. 3A and 3B for ease of description, but which may be substantially similar to the casing 120), such as for a purpose of protecting internal components of the apparatuses 300, 312 (e.g., the semiconductor dies 302, the vertical interconnect bridges 308, the pillar interconnects 311, or similar components) from damage and environmental elements (e.g., particles) that can lead to malfunction of the apparatuses 300, 312. In such implementations, the casing may be a mold compound (e.g., an epoxy molding compound (EMC)), a plastic (e.g., an epoxy plastic), a ceramic, or another type of material that at least partially surrounds the internal components of the apparatuses 300, 312. Aspects of implementing a casing in connection with apparatus including stacked semiconductor dies 302 and at least vertical interconnect bridge 308 are described in more detail below in connection with FIGS. 4F-4G.

The illustrated x-axis and z-axis are substantially perpendicular to each other. In other words, the x-axis is substantially perpendicular to the z-axis and a y-axis (e.g., an axis not shown in the figures but which extends into or out of the elevation views shown in the figures), the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

As indicated above, FIGS. 3A-3B are provided as examples. Other examples may differ from what is described with respect to FIGS. 3A-3B.

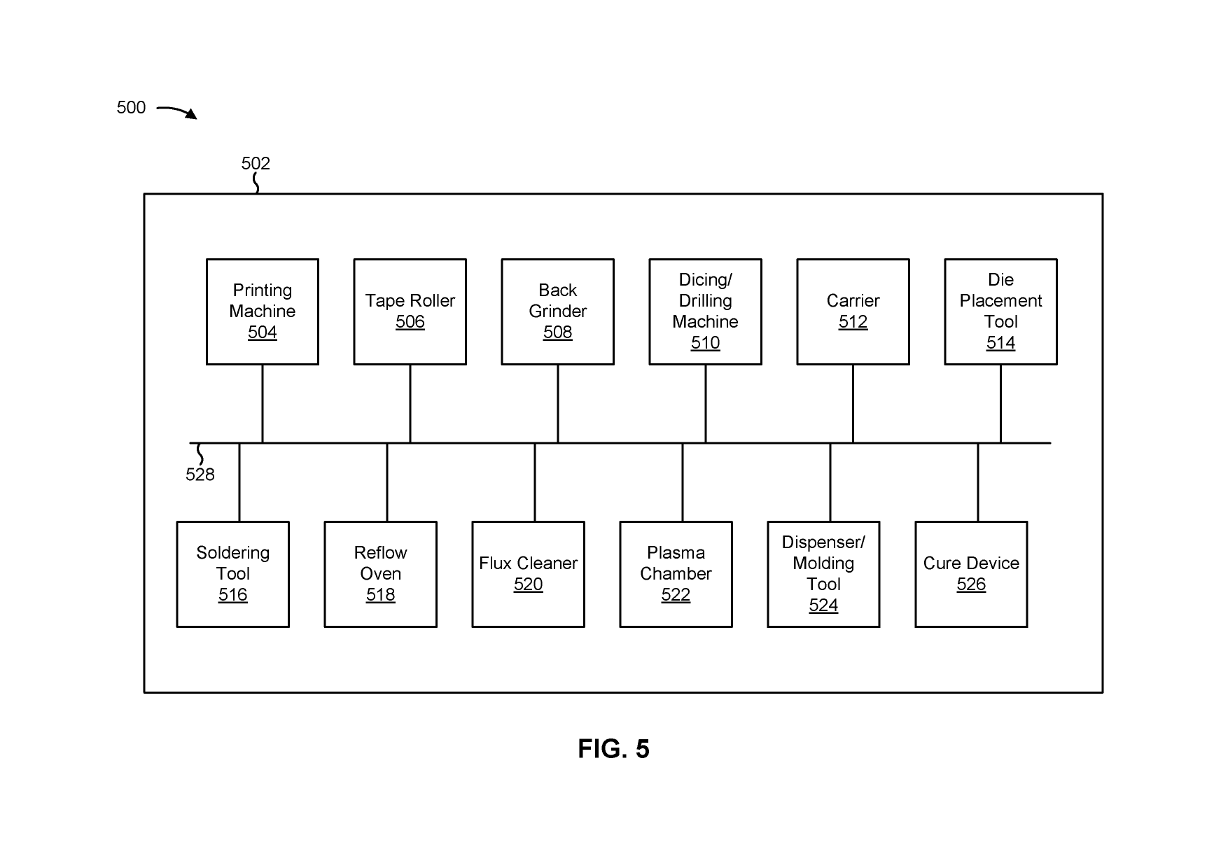

FIGS. 4A-4G are diagrams of an example process 400 used to fabricate a semiconductor package including a vertical interconnect bridge. More particularly, FIGS. 4A-4G are diagrams of an example process 400 that may be used to fabricate the apparatus 300 described above in connection with FIG. 3A. Although for ease of description process 400 is described in connection with the apparatus 300, in some other implementations, the example process 400 may be used to fabricate other semiconductor packages, such as the apparatus 312 described above in connection with FIG. 3B or another semiconductor package implementing stacked semiconductor dies and vertical interconnect bridges (e.g., other 4H semiconductor packages, other 6H semiconductor packages, 8H semiconductor packages, 12H semiconductor packages, 16H semiconductor packages, or similar semiconductor packages). The fabrication process 400 shown and described in connection with FIGS. 4A-4G may be performed using various semiconductor manufacturing equipment, such as the semiconductor manufacturing equipment described below in connection with FIG. 5.

In some implementations, a vertical interconnect bridge 308 may be manufactured or attached to the interconnect structure 304 separate from the semiconductor die stack. For example, the vertical interconnect bridge 308 may be bonded to the interconnect structure 304 in a first process (e.g., a first subprocess of process 400), the semiconductor dies 302 may be bonded to each other forming a semiconductor die stack in a second process (e.g., a second subprocess of process 400), and the semiconductor die stack may be bonded to the interconnect structure 304 (with the vertical interconnect bridge bonded thereto) in a third process (e.g., a third subprocess of process 400).

In that regard, and as shown in FIG. 4A, process 400 may include bonding the vertical interconnect bridge 308 to the interconnect structure 304. In some implementations, the vertical interconnect bridge 308 may be bonded to the interconnect structure 304 using a flip-chip and reflow process, among other examples. More particularly, the vertical interconnect bridge 308 may be a flip-chip die manufactured with multiple bumps (e.g., micro bumps, solder bumps or balls, pillar bumps, or similar bumps) or pads facing upward, in the z-axis direction, and then flipped during the chip attachment process shown in FIG. 4A such that the bumps or pads face the interconnect structure 304 and are bonded thereto. In such implementations, bonds (e.g., solder bonds) may be formed between the vertical interconnect bridge 308 and the interconnect structure 304 using a reflow process, a thermal compression bonding (TCB) process, or a similar process.

As shown in FIG. 4B, process 400 may include coating (e.g., laminating) a carrier 402 with a debonding layer 404 (sometimes referred to herein as a release layer or a sacrificial layer). In some implementations, the carrier 402 may be a wafer-shaped carrier (e.g., in wafer-based fabrication processes), a panel-shaped carrier (e.g., in panel-based fabrication processes), a strip-shaped carrier (e.g., in strip-based fabrication processes), or a similar carrier. The carrier 402 may be constructed from any suitable material used in a semiconductor package manufacturing process. In some implementations, the carrier 402 may be a glass carrier, which may aid in a laser-debonding process. In some implementations, the debonding layer 404 may aid during a debonding process (e.g., a laser-debonding process or another debonding process) by enabling the carrier 402 to be easily removed from a semiconductor package after package formation, which is described in more detail below in connection with FIG. 4D.

As shown in FIG. 4C, process 400 may include a die attach step that includes attaching the semiconductor dies 302 to one another on the carrier 402. For example, the fourth semiconductor die 302-4 (e.g., the uppermost semiconductor die 302 shown in FIG. 3A) may be placed on the carrier 402 in an upside-down orientation as compared to the orientation of the fourth semiconductor die 302-4 shown in FIG. 3A (e.g., such that the fourth DAF 306-4 faces the carrier 402 and abuts the debonding layer 404).

The third semiconductor die 302-3 may then be placed on the fourth semiconductor die 302-4 in an upside-down orientation as compared to the orientation of the third semiconductor die 302-3 shown in FIG. 3A, and may be coupled or bonded to the fourth semiconductor die 302-4 via the third DAF 306-3. Similarly, the second semiconductor die 302-2 may be placed on the third semiconductor die 302-3 in an upside-down orientation as compared to the orientation of the second semiconductor die 302-2 shown in FIG. 3A, and may be coupled or bonded to the third semiconductor die 302-3 via the second DAF 306-2, and the first semiconductor die 302-1 may be placed on the second semiconductor die 302-2 in an upside-down orientation as compared to the orientation of the first semiconductor die 302-1 shown in FIG. 3A, and may be coupled or bonded to the second semiconductor die 302-2 via the first DAF 306-1.

As part of the die attach process shown in FIG. 4C, one or more bumps, pillars, pads, or similar components may be formed on the semiconductor die stack, which may be used in a later step of process 400 to bond the semiconductor die stack to the interconnect structure 304 or vertical interconnect bridge 308. For example, the first pillar interconnects 311-1 may be formed at the fourth semiconductor die 302-4 or the second pillar interconnects 311-2 may be formed at the second semiconductor die 302-2. In some implementations, the pillar interconnects 311 may be formed by building up or plating conductive material (e.g., copper) at desired locations. Additionally, or alternatively, process 400 may form one or more micro bumps 410 (e.g., solder bumps, pillar bumps, and/or other bumps) or similar electrical connections on upward facing (in the orientation shown in FIG. 4C) faces of the semiconductor dies 302 or pillar interconnects 311, which may be used in a later reflow step or similar bonding step to electrically connect the semiconductor die stack to the interconnect structure 304 or the vertical interconnect bridge 308.

As shown in FIG. 4D, and as schematically indicated by double-sided arrow 412, process 400 may include debonding the semiconductor die stack from the carrier 402. In some implementations, a debonding process (sometimes referred to as a wafer-level debonding process and/or a panel-level debonding process) may be used to debond the carrier 402 from the semiconductor die stack. In some implementations, the carrier 402 or the debonding layer 404 may be debonded from the semiconductor die stack via a laser debonding process. In some implementations, debonding the carrier 402 or the debonding layer 404 from the semiconductor die stack may include cleaning a bottom (in the z-axis direction) surface of the semiconductor die stack in order to remove residual adhesives, portions of the debonding layer 404 (e.g., portions of the sacrificial layer), or similar contaminants following removal of the carrier 402.

As indicated by FIG. 4E, process 400 may include bonding the semiconductor die stack to the interconnect structure 304 and the vertical interconnect bridge 308. In some implementations, and in a similar manner as described above in connection with bonding the vertical interconnect bridge 308 to the interconnect structure 304, the semiconductor die stack may be bonded to the interconnect structure 304 using a flip-chip and reflow process, among other examples. More particularly, the semiconductor die stack may be manufactured with multiple bumps (e.g., micro bumps, solder bumps or balls, pillar bumps, or similar bumps) or pads facing upward, in the z-axis direction (as described above in connection with FIG. 4C), and then flipped during the chip attachment process shown in FIG. 4E such that the bumps or pads face the interconnect structure 304 and vertical interconnect bridge 308 and are bonded thereto. In such implementations, bonds (e.g., solder bonds) may be formed between the semiconductor die stack and the interconnect structure 304 or the vertical interconnect bridge 308 using a reflow process, a TCB process, or a similar process.

As described above in connection with FIGS. 3A and 3B, in some implementations, a semiconductor package may optionally include a casing (e.g., mold compound) to protect the internal components from contamination or a surrounding environment, among other examples. In such implementations, and as shown in FIG. 4F, process 400 may optionally include encasing the stack of semiconductor dies 302, the vertical interconnect bridge 308, the pillar interconnects 311, or other components of the semiconductor device assembly in a mold compound 414 (e.g., an EMC or a similar mold compound). In some implementations, encasing the semiconductor dies 302, the vertical interconnect bridge 308, the pillar interconnects 311, or other components of the semiconductor device assembly in the mold compound 414 may be associated with a compression molding process (e.g., a wafer-level compression molding process and/or a panel-level compression molding process). In some implementations, the compression molding process may result in overmolding, in which the mold compound 414 extends higher, in the z-axis direction, than is otherwise desired for the semiconductor package (e.g., the mold compound 414 may extend beyond certain design specifications). In such implementations, additional mold processing steps may optionally be performed, such as back-grinding, through-package post revealing, or a similar process.

More particularly, as shown in FIG. 4G, process 400 may optionally include grinding the mold compound 414 to remove a portion of the mold compound 414. In some implementations, grinding the mold compound 414 may be performed for purposes of exposing a face 416 of the fourth semiconductor die 302-4, among other examples. Put another way, process 400 may include grinding the mold compound 414 to expose a face 416 of at least one semiconductor die 302 (e.g., an uppermost stacked semiconductor die 302, such as the fourth semiconductor die 302-4 in the example shown in FIG. 4G). Exposing the face 416 of the fourth semiconductor die 302-4 outside of the mold compound 414 (e.g., the EMC) may improve heat dissipation or a thermal performance of the fourth semiconductor die 302-4 by exposing the fourth semiconductor die 302-4 to a surrounding environment when the semiconductor package is mounted to a substrate (e.g., a printed circuit board (PCB)) of a higher level system, among other examples.

As indicated above, FIGS. 4A-4G are provided as an example. Other examples may differ from what is described with respect to FIGS. 4A-4G.

FIG. 5 is a diagram of example equipment 500 used to manufacture various semiconductor packages, semiconductor dies, memory devices, or similar components described herein. In some implementations, the equipment 500 may be used to manufacture the apparatus 300, the apparatus 312, the semiconductor package described above in connection with FIGS. 4A-4G, or a similar semiconductor package. As shown in FIG. 5, the equipment 500 may include a packaging system 502. The packaging system 502 may include one or more devices or tooling, such as a printing machine 504, a tape roller 506, a back grinder 508, a dicing and/or drilling machine 510, a carrier 512, a die placement tool 514, a soldering tool 516, a reflow oven 518, a flux cleaner 520, a plasma chamber 522, a dispenser and/or molding tool 524, and/or a cure device 526. One or more devices may be may physically or communicatively coupled to one another. For example, one or more devices may interconnect via wired connections and/or wireless connections, such as via a bus 528. Additionally, or alternatively, one or more devices may form part of an electronics assembly manufacturing line.

The printing machine 504 may be a device capable of printing patterns in a material such as silicon, a dielectric material, a polyimide layer, or a similar material, for purposes of forming an integrated circuit, an RDL, or the like. In some implementations, the printing machine 504 may be a lithography device capable of printing patterns in a material to form an integrated circuit.

The tape roller 506 may be a device capable of laminating a tape (e.g., a back grinding tape) on a semiconductor wafer and/or a semiconductor die. The tape roller 506 may be capable of applying pressure to a tape as the tape is being laminated onto a wafer or a die.

The back grinder 508 may be a device capable of grinding a backside of a semiconductor wafer, a semiconductor die, and/or a semiconductor device assembly, thereby reducing a thickness of the wafer, die, and/or semiconductor device assembly to a desired thickness (e.g., as described above in connection with FIG. 4G). In some implementations, the back grinder 508 may be associated with a rotary table, a chuck table, and/or a grinding wheel for purposes of grinding a wafer, a die, and/or an assembly to a suitable thickness.

The dicing and/or drilling machine 510 may be a device capable of dicing a die, such as a microcontroller, a memory die, or other semiconductor die, from a wafer. In some implementations, the dicing and/or drilling machine 510 may include one or more dicing blades and/or one or more lasers to dice a die from the wafer. In some implementations, the dicing and/or drilling machine 510 may be a device capable of drilling through vias in a mold compound. For example, the dicing and/or drilling machine 510 may include a laser capable of drilling through vias in a mold compound.

The carrier 512 may be a device capable of supporting and/or carrying a substrate during a die and/or chip attachment process, during a compression molding process, or during a similar process. The carrier 512 may be constructed from a non-contaminating material, such as quartz, glass, or a similar material, and may be capable of withstanding high temperatures. In that regard, the carrier 512 may be capable of carrying a substrate and/or one or more die through one or more ovens, such as a reflow oven 518 and/or a cure device 526.

The die placement tool 514 may be a high-precision tool capable of placing a die onto a substrate, an RDL, or similar mounting surface. In some implementations, the die placement tool 514 may be capable of flipping a flip chip die during a placement process, such that an active surface of the flip chip die, which may be facing up during preliminary manufacturing steps, may face the substrate during the flip chip die placement process. In some implementations, the die placement tool 514 may include one or more sensors capable of aligning bump bonds on a die with bond pads on a substrate during a flip chip die attachment process. In some implementations, the die placement tool may be configured to place a die attach component between a die a substrate, such as a DAF that couples the die to the substrate.

The soldering tool 516 may be capable of forming one or more solder connections between components of a semiconductor package. For example, the soldering tool 516 may be capable of forming wire bond connections between components of a semiconductor package by soldering wires connecting wire bond pads from one component to wire bond pads of another component. In some examples, the soldering tool 516 may be capable of applying a solder paste to between electrical contacts of electronic components, such as between electrical contacts provided on a semiconductor component and corresponding electrical contacts provided on a substrate and/or an RDL. Additionally, or alternatively, the soldering tool 516 may be capable of applying solder or other electrically conductive material to form a portion of an electrical connection to be formed between a die and a substrate. For example, the soldering tool 516 may be capable of applying a grid of solder bumps (e.g., micro balls) to a die and/or a molded die assembly, which will align with a grid of bump pads on a substrate during a flip chip attachment process, or the like.

The reflow oven 518 may be a device capable of heating components to a suitable temperature to cause a reflow of solder or other bonding material, thereby causing the solder or similar material to melt and make an electrical connection between two components.

The flux cleaner 520 may be a device capable of removing residual flux from a soldering process. In some implementations, the flux cleaner 520 may include a heater capable of removing residual flux through a heat treatment process. Additionally, or alternatively, the flux cleaner 520 may include a nozzle or similar device capable of applying a cleaning agent to a component in order to remove residual flux therefrom.

The plasma chamber 522 may be a device capable of providing plasma treatment to a component. In some implementations, the plasma chamber 522 may be capable of directly or indirectly applying a plasma stream to an area of a component, such as for purposes of preparing the area on the component for receiving an epoxy underfill, or the like.

The dispenser and/or molding tool 524 may be a device capable of dispensing a filler material around a die or similar component. In some implementations, the dispenser and/or molding tool 524 may be capable of dispensing a mold compound (e.g., an epoxy mold compound) during a compression molding process. In some implementations, the dispenser and/or molding tool 524 may include a dispensing needle capable of applying an epoxy underfill by capillary action under pressure, such as by dispensing underfill material around a periphery of a die and/or other electrical component such that the underfill material flows beneath the die and/or other electrical component and fills a space between the die and/or other electrical component and a substrate.

The cure device 526 may be a device capable of curing a material, such as an ultraviolet (UV) curable adhesive layer, a mold compound, such as an epoxy mold compound, an epoxy underfill material, a moldable underfill (MUF) material, or a similar material. In some implementations, the cure device 526 may include a UV lamp capable of irradiating a back grinding tape with UV light in order to cure an adhesive layer thereof. In some implementations, the cure device 526 may be an oven configured to heat a mold compound to a suitable curing temperature. Additionally, or alternatively, the cure device 526 may be capable of curing a mold compound via a chemical reaction, by the application of UV light, by the application of other radiation, or the like.

The number and arrangement of devices and networks shown in FIG. 5 are provided as an example. In practice, there may be additional devices, fewer devices, different devices, or differently arranged devices than those shown in FIG. 5. Furthermore, two or more devices shown in FIG. 5 may be implemented within a single device, or a single device shown in FIG. 5 may be implemented as multiple, distributed devices. Additionally, or alternatively, a set of devices (e.g., one or more devices) of equipment 500 may perform one or more functions described as being performed by another set of devices of equipment 500.

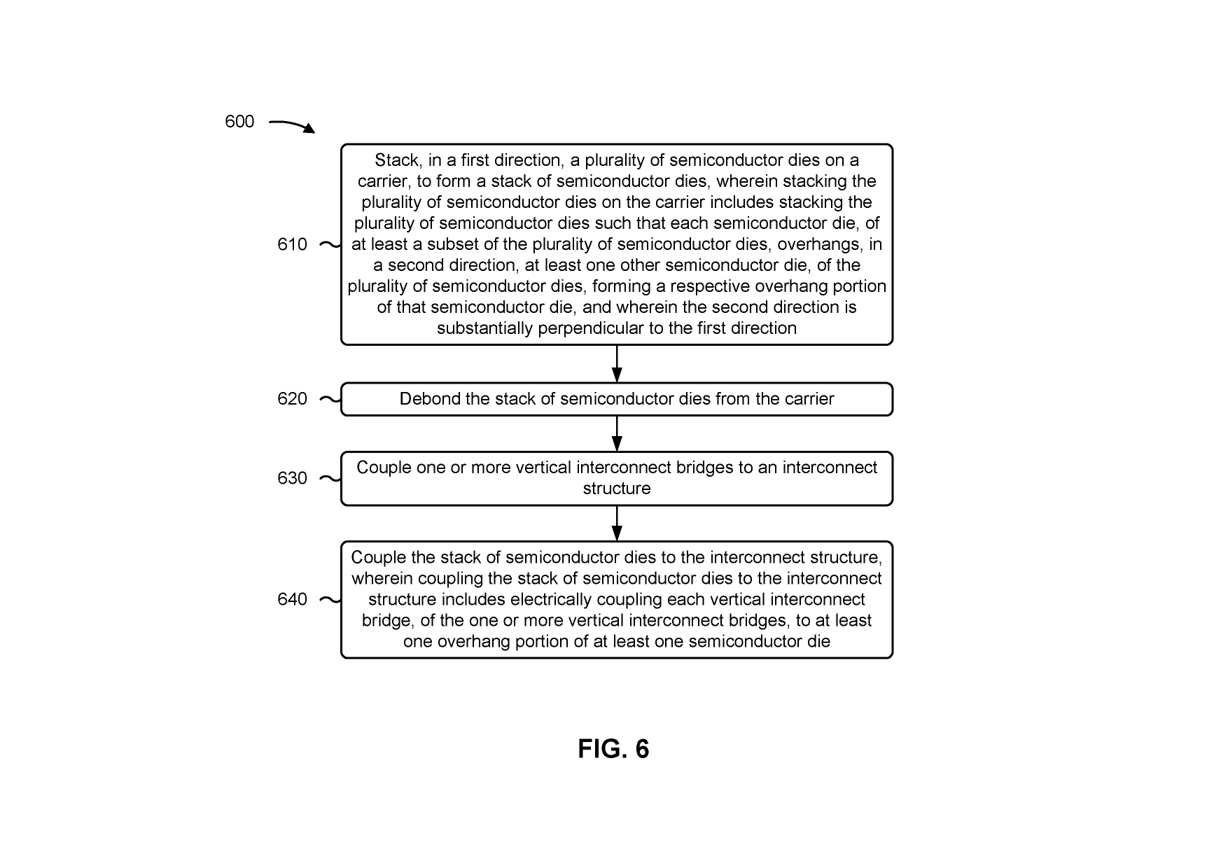

FIG. 6 is a flowchart of an example method 600 of forming an integrated assembly or memory device having one or more vertical interconnect bridges. In some implementations, one or more process blocks of FIG. 6 may be performed by various semiconductor manufacturing equipment, such as the equipment 500 described above in connection with FIG. 5.

As shown in FIG. 6, the method 600 may include stacking, in a first direction, a plurality of semiconductor dies on a carrier, to form a stack of semiconductor dies, wherein stacking the plurality of semiconductor dies on the carrier includes stacking the plurality of semiconductor dies such that each semiconductor die, of at least a subset of the plurality of semiconductor dies, overhangs, in a second direction, at least one other semiconductor die, of the plurality of semiconductor dies, forming a respective overhang portion of that semiconductor die, and wherein the second direction is substantially perpendicular to the first direction (block 610). As further shown in FIG. 6, the method 600 may include debonding the stack of semiconductor dies from the carrier (block 620). As further shown in FIG. 6, the method 600 may include coupling one or more vertical interconnect bridges to an interconnect structure (block 630). As further shown in FIG. 6, the method 600 may include coupling the stack of semiconductor dies to the interconnect structure, wherein coupling the stack of semiconductor dies to the interconnect structure includes electrically coupling each vertical interconnect bridge, of the one or more vertical interconnect bridges, to at least one overhang portion of at least one semiconductor die (block 640).

The method 600 may include additional aspects, such as any single aspect or any combination of aspects described below and/or in connection with one or more other methods described elsewhere herein.

In a first aspect, the method 600 includes encasing the stack of semiconductor dies and the one or more vertical interconnect bridges in a mold compound.

In a second aspect, alone or in combination with the first aspect, the method 600 includes grinding the mold compound to expose a face of at least one semiconductor die, of the plurality of semiconductor dies.

In a third aspect, alone or in combination with one or more of the first and second aspects, coupling the one or more vertical interconnect bridges to the interconnect structure includes coupling a first vertical interconnect bridge, of the one or more vertical interconnect bridges, and a second vertical interconnect bridge, of the one or more vertical interconnect bridges, to the interconnect structure, wherein a first dimension, in the first direction, of the first vertical interconnect bridge is smaller than a second dimension, in the first direction, of the second vertical interconnect bridge.

In a fourth aspect, alone or in combination with one or more of the first through third aspects, stacking the plurality of semiconductor dies on the carrier includes coupling adjacent semiconductor dies, of the plurality of semiconductor dies, to each other using a die attach film.

In a fifth aspect, alone or in combination with one or more of the first through fourth aspects, the method 600 includes forming a plurality of pillar bonds on at least an overhang portion of a first semiconductor die, of the plurality of semiconductor dies, wherein coupling the stack of semiconductor dies to the interconnect structure includes electrically coupling the plurality of pillar bonds to a first vertical interconnect bridge, of the one or more vertical interconnect bridges.

In a sixth aspect, alone or in combination with one or more of the first through fifth aspects, coupling the one or more vertical interconnect bridges to the interconnect structure includes coupling the one or more vertical interconnect bridges to the interconnect structure using at least one of a flip-chip process or a reflow process.

In a seventh aspect, alone or in combination with one or more of the first through sixth aspects, coupling the stack of semiconductor dies to the interconnect structure includes coupling the stack of semiconductor dies to the interconnect structure using at least one of a flip-chip process or a reflow process.

In an eighth aspect, alone or in combination with one or more of the first through seventh aspects, the method 600 includes coating the carrier with a debonding layer, wherein stacking the plurality of semiconductor dies on the carrier includes stacking the plurality of semiconductor dies on the debonding layer.

Although FIG. 6 shows example blocks of the method 600, in some implementations, the method 600 may include additional blocks, fewer blocks, different blocks, or differently arranged blocks than those depicted in FIG. 6. In some implementations, the method 600 may include forming the apparatus 300 or the apparatus 312, an integrated assembly that includes the apparatus 300 or the apparatus 312, any part described herein of the apparatus 300 or the apparatus 312, and/or any part described herein of an integrated assembly that includes the apparatus 300 or the apparatus 312. For example, the method 600 may include forming one or more of the semiconductor dies 302, interconnect structure 304, DAFs 306, vertical interconnect bridges 308, pillar interconnects 311, or mold compound 414.

In some implementations, a semiconductor device assembly includes a plurality of semiconductor dies stacked on an interconnect structure in a first direction, wherein a first semiconductor die, of the plurality of semiconductor dies, overhangs a second semiconductor die, of the plurality of semiconductor dies, in a second direction, forming a first overhang portion of the first semiconductor die, and wherein the second direction is substantially perpendicular to the first direction; and a first vertical interconnect bridge disposed on the interconnect structure, wherein the first vertical interconnect bridge is electrically coupled to the first overhang portion of the first semiconductor die and provides an electrical connection between the first semiconductor die and the interconnect structure.

In some implementations, a semiconductor package includes a base semiconductor die electrically coupled to an interconnect structure; a plurality of stacked semiconductor dies that are stacked on the base semiconductor die in a first direction, wherein each stacked semiconductor die, of the plurality of stacked semiconductor dies, overhangs, in a second direction, at least one of the base semiconductor die or another stacked semiconductor die, forming a respective overhang portion of that semiconductor die, and wherein the second direction is substantially perpendicular to the first direction; and one or more vertical interconnect bridges disposed on the interconnect structure, wherein each vertical interconnect bridge, of the one or more vertical interconnect bridges, is electrically coupled to at least one overhang portion of at least one stacked semiconductor die and provides an electrical connection between the at least one semiconductor die and the interconnect structure.

In some implementations, a method includes stacking, in a first direction, a plurality of semiconductor dies on a carrier, to form a stack of semiconductor dies, wherein stacking the plurality of semiconductor dies on the carrier includes stacking the plurality of semiconductor dies such that each semiconductor die, of at least a subset of the plurality of semiconductor dies, overhangs, in a second direction, at least one other semiconductor die, of the plurality of semiconductor dies, forming a respective overhang portion of that semiconductor die, and wherein the second direction is substantially perpendicular to the first direction; debonding the stack of semiconductor dies from the carrier; coupling one or more vertical interconnect bridges to an interconnect structure; and coupling the stack of semiconductor dies to the interconnect structure, wherein coupling the stack of semiconductor dies to the interconnect structure includes electrically coupling each vertical interconnect bridge, of the one or more vertical interconnect bridges, to at least one overhang portion of at least one semiconductor die.

The foregoing disclosure provides illustration and description but is not intended to be exhaustive or to limit the implementations to the precise forms disclosed. Modifications and variations may be made in light of the above disclosure or may be acquired from practice of the implementations described herein.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element’s relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.”

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a + b, a + c, b + c, and a + b + c, as well as any combination with multiples of the same element (e.g., a + a, a + a + a, a + a + b, a + a + c, a + b + b, a + c + c, b + b, b + b + b, b + b + c, c + c, and c + c + c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device assembly, comprising:
a plurality of semiconductor dies stacked on an interconnect structure in a first direction,
wherein a first semiconductor die, of the plurality of semiconductor dies, overhangs a second semiconductor die, of the plurality of semiconductor dies, in a second direction, forming a first overhang portion of the first semiconductor die, and
wherein the second direction is substantially perpendicular to the first direction; and
a first vertical interconnect bridge disposed on the interconnect structure,
wherein the first vertical interconnect bridge is electrically coupled to the first overhang portion of the first semiconductor die and provides an electrical connection between the first semiconductor die and the interconnect structure.

2. The semiconductor device assembly of claim 1, wherein the first semiconductor die is directly coupled to the first vertical interconnect bridge.

3. The semiconductor device assembly of claim 1, further comprising a die attach film, disposed between the first semiconductor die and the second semiconductor die, that couples the first semiconductor die to the second semiconductor die.

4. The semiconductor device assembly of claim 1, wherein a third semiconductor die, of the plurality of semiconductor dies, overhangs the first semiconductor die in the second direction, forming a second overhang portion of the third semiconductor die, and
wherein the first vertical interconnect bridge is electrically coupled to the second overhang portion of the third semiconductor die and provides an electrical connection between the third semiconductor die and the interconnect structure.

5. The semiconductor device assembly of claim 4, wherein the third semiconductor die is electrically coupled to the first vertical interconnect bridge via at least one of a plurality of pillar connections or a plurality of wire connections.

6. The semiconductor device assembly of claim 4, further comprising a die attach film disposed between the first semiconductor die and the third semiconductor die that couples the first semiconductor die to the third semiconductor die.

7. The semiconductor device assembly of claim 1, further comprising a second vertical interconnect bridge disposed on the interconnect structure,
wherein a third semiconductor die, of the plurality of semiconductor dies, overhangs the first semiconductor die in the second direction, forming a second overhang portion of the third semiconductor die, and
wherein the second vertical interconnect bridge is electrically coupled to the second overhang portion of the third semiconductor die and provides an electrical connection between the third semiconductor die and the interconnect structure.

8. The semiconductor device assembly of claim 7, wherein a first dimension, in the first direction, of the first vertical interconnect bridge is smaller than a second dimension, in the first direction, of the second vertical interconnect bridge.

9. A semiconductor package, comprising:
a base semiconductor die electrically coupled to an interconnect structure;
a plurality of stacked semiconductor dies that are stacked on the base semiconductor die in a first direction,
wherein each stacked semiconductor die, of the plurality of stacked semiconductor dies, overhangs, in a second direction, at least one of the base semiconductor die or another stacked semiconductor die, forming a respective overhang portion of that semiconductor die, and
wherein the second direction is substantially perpendicular to the first direction; and
one or more vertical interconnect bridges disposed on the interconnect structure,
wherein each vertical interconnect bridge, of the one or more vertical interconnect bridges, is electrically coupled to at least one overhang portion of at least one stacked semiconductor die and provides an electrical connection between the at least one semiconductor die and the interconnect structure.

10. The semiconductor package of claim 9, wherein a first vertical interconnect bridge, of the one or more vertical interconnect bridges, is directly coupled to a first stacked semiconductor die, of the plurality of stacked semiconductor dies, and
wherein the first vertical interconnect bridge is electrically coupled to a second stacked semiconductor die, of the plurality of stacked semiconductor dies, via at least one of a plurality of pillar connections or a plurality of wire connections.

11. The semiconductor package of claim 9, further comprising a die attach film, disposed between the base semiconductor die and a first stacked semiconductor die, of the plurality of stacked semiconductor dies, that couples the base semiconductor die to the first stacked semiconductor die.

12. The semiconductor package of claim 9, wherein the one or more vertical interconnect bridges includes a first vertical interconnect bridge and a second vertical interconnect bridge, and
wherein a first dimension, in the first direction, of the first vertical interconnect bridge is smaller than a second dimension, in the first direction, of the second vertical interconnect bridge.

13. The semiconductor package of claim 9, further comprising an epoxy molding compound at least partially surrounding the base semiconductor die, the plurality of stacked semiconductor dies, and the one or more vertical interconnect bridges.

14. The semiconductor package of claim 13, wherein a face of an uppermost stacked semiconductor die, of the plurality of semiconductor dies, is exposed outside of the epoxy molding compound.

15. A method, comprising:
stacking, in a first direction, a plurality of semiconductor dies on a carrier, to form a stack of semiconductor dies,
wherein stacking the plurality of semiconductor dies on the carrier includes stacking the plurality of semiconductor dies such that each semiconductor die, of at least a subset of the plurality of semiconductor dies, overhangs, in a second direction, at least one other semiconductor die, of the plurality of semiconductor dies, forming a respective overhang portion of that semiconductor die, and
wherein the second direction is substantially perpendicular to the first direction;
debonding the stack of semiconductor dies from the carrier;
coupling one or more vertical interconnect bridges to an interconnect structure; and
coupling the stack of semiconductor dies to the interconnect structure,
wherein coupling the stack of semiconductor dies to the interconnect structure includes electrically coupling each vertical interconnect bridge, of the one or more vertical interconnect bridges, to at least one overhang portion of at least one semiconductor die.

16. The method of claim 15, further comprising encasing the stack of semiconductor dies and the one or more vertical interconnect bridges in a mold compound.

17. The method of claim 16, further comprising grinding the mold compound to expose a face of at least one semiconductor die, of the plurality of semiconductor dies.

18. The method of claim 15, wherein coupling the one or more vertical interconnect bridges to the interconnect structure includes coupling a first vertical interconnect bridge, of the one or more vertical interconnect bridges, and a second vertical interconnect bridge, of the one or more vertical interconnect bridges, to the interconnect structure,
wherein a first dimension, in the first direction, of the first vertical interconnect bridge is smaller than a second dimension, in the first direction, of the second vertical interconnect bridge.

19. The method of claim 15, wherein stacking the plurality of semiconductor dies on the carrier includes coupling adjacent semiconductor dies, of the plurality of semiconductor dies, to each other using a die attach film.

20. The method of claim 15, further comprising forming a plurality of pillar bonds on at least an overhang portion of a first semiconductor die, of the plurality of semiconductor dies,
wherein coupling the stack of semiconductor dies to the interconnect structure includes electrically coupling the plurality of pillar bonds to a first vertical interconnect bridge, of the one or more vertical interconnect bridges.

21. The method of claim 15, wherein coupling the one or more vertical interconnect bridges to the interconnect structure includes coupling the one or more vertical interconnect bridges to the interconnect structure using at least one of a flip-chip process or a reflow process.

22. The method of claim 15, wherein coupling the stack of semiconductor dies to the interconnect structure includes coupling the stack of semiconductor dies to the interconnect structure using at least one of a flip-chip process or a reflow process.

23. The method of claim 15, further comprising coating the carrier with a debonding layer,
wherein stacking the plurality of semiconductor dies on the carrier includes stacking the plurality of semiconductor dies on the debonding layer.
